(19) United States
(12) Patent Application Publication
(10) Pub. No.: US 2009/0004405 A1
(43) Pub. Date: Jan. 1, 2009

(54) Thermal Batch Reactor with Removable Susceptors

(75) Inventors: Nir Merry, Mountain View, CA (US); Joseph Yudovsky, Campbell, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 11/771,800

(22) Filed: Jun. 29, 2007

(51) Int. Cl. C23C 16/455

(52) U.S. Cl. 427/585; 118/724; 428/34.1

(57) ABSTRACT

An apparatus and method for uniform heating and gas flow in a batch processing chamber are provided. The apparatus includes a quartz chamber body, removable heater blocks which surround the quartz chamber body, an inject assembly coupled to one side of the quartz chamber body, and a substrate boat having removable susceptors. In one embodiment, the boat may be configured with a plurality of susceptors to control substrate heating during batch processing.

### BACKGROUND OF THE INVENTION

1. Field of the Invention

Embodiments of the present invention generally relate to a batch processing chamber. More particularly, embodiments of the invention relate to methods and apparatus for uniform substrate heating and uniform gas delivery in a batch processing chamber.

2. Description of the Related Art

The term batch processing generally refers to the processing of two or more substrates at the same time in one reactor. There are several advantages to batch processing of substrates. Batch processing can increase the throughput of a substrate processing system by performing a process recipe step that is disproportionately long compared to other process recipe steps in a substrate processing sequence. The use of batch processing for the longer recipe step effectively decreases the processing time per substrate. Another advantage of batch processing may be realized in some processing steps where expensive precursor materials are used, such as ALD and CVD, by greatly reducing the usage of precursor gases per substrate as compared to single substrate processing. The use of batch processing reactors may also result in smaller system footprints as compared to cluster tools which include multiple single substrate processing reactors.

Two advantages of batch processing, which may be summarized as increased throughput and reduced processing cost per substrate, directly affect two related and important factors, which are device yield and cost of ownership (COO). These factors are important since they directly affect the cost to produce an electronic device and, thus, a device manufacturer's competitiveness in the market place. Batch processing is often desirable since it can be effective in increasing device yield and decreasing COO.

Batch processing of many substrates may create variations in temperature and gas flow across each substrate within the batch, and from batch to batch. Such variations in temperature and gas flow dynamics may cause variations in the properties of a film deposited across the surface of each substrate. The push in the industry to shrink the size of semiconductor devices to improve device processing speed and reduce the generation of heat by the device has reduced the tolerance window for film property variation across the substrate surface. Smaller semiconductor devices may also require lower processing temperatures and shorter heating durations (low thermal budget processing) to prevent damaging the device features. As a result, low thermal budget processing and uniform temperature and gas flow across each substrate are often desirable.

The desire for lower thermal budgets and better control of both gas flow dynamics and substrate temperature has led to the development of single substrate processing chambers that use radiant heating. Radiant heating makes possible a more uniform temperature profile across the substrate surface while also reducing the thermal budget required for the deposition process. Chamber components with high thermal conductivities, high emissivities, and low thermal mass may also be used to provide more uniform radiant heating of the substrate while maintaining a low thermal budget. The single substrate processing chamber, however, usually has lower throughput and higher processing cost per substrate than a batch processing chamber.

Therefore, there is a need for a batch processing chamber that can provide more uniform substrate heating and more uniform gas flow.

### SUMMARY OF THE INVENTION

The present invention generally provides an apparatus and method for the heating of substrates and the injection and removal of process gases in a batch processing chamber.

One embodiment provides an outer chamber configured to enclose a quartz chamber and at least one removable heater block, the quartz chamber configured to enclose a process volume, at least one removable heater block disposed outside the quartz chamber, the heater block having one or more heating zones, an inject assembly attached to the quartz chamber for injecting one or more process gases into the chamber, an exhaust pocket disposed on a side of the quartz chamber and opposite to the inject assembly, and a substrate boat adapted for holding a plurality of substrates and removable susceptors such that one or more substrates are disposed between susceptor pairs.

In another embodiment, a method is provided for disposing a substrate boat loaded with substrates and susceptors into a process volume defined by a quartz chamber, heating radiantly the substrates and susceptors, delivering a process gas through an inject assembly having one or more independent vertical channels, and injecting the process gas into a process volume through a plurality of holes disposed in the inject assembly.

One embodiment of provides a substrate boat for a batch processing chamber. The substrate boat comprises two or more vertical supports, support fingers, and both a base plate and a top plate coupled to the vertical supports. The substrate boat is adapted for holding a plurality of substrates and removable susceptors such that the boat susceptors may be loaded into or unloaded from the boat using a substrate-handling robot.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic side view of one embodiment of a batch processing chamber with a substrate boat in a processing position.

FIG. 2 is a schematic cross-sectional top view of the batch processing chamber shown in FIG. 1.

FIGS. 3A-3C are enlarged views of different embodiments of the substrate boat with removable susceptors shown in FIG. 1.

FIG. 4 is a cross-sectional top view of the substrate boat shown in FIG. 3A.

FIG. 5 is an isometric view of one embodiment of the substrate boat shown in FIG. 1.

To facilitate understanding, identical reference numerals have been used, where possible, to designate identical elements that are common to the figures.

### DETAILED DESCRIPTION

The present invention generally provides a method and apparatus for a batch processing chamber that provides uniform heating and gas flow for a plurality of substrates disposed within a quartz reaction chamber.

The batch processing chamber described herein may also be used to improve substrate throughtput when used for chemical vapor deposition (CVD) and atomic layer deposition (ALD) processes that may have low deposition rates. For example, the chamber of the present invention may be used to deposit silicon-containing and hafnium-containing films, such as hafnium oxide or hafnium silicate (i.e., hafnium silicon oxide), using an ALD type process. Since hafnium oxide or hafnium silicate deposition rate is slow, for example, the time to deposit 30 angstroms can take on the order of about 200 minutes, this disproportionately long process step is advantageously performed in the batch processing chamber of the present invention.

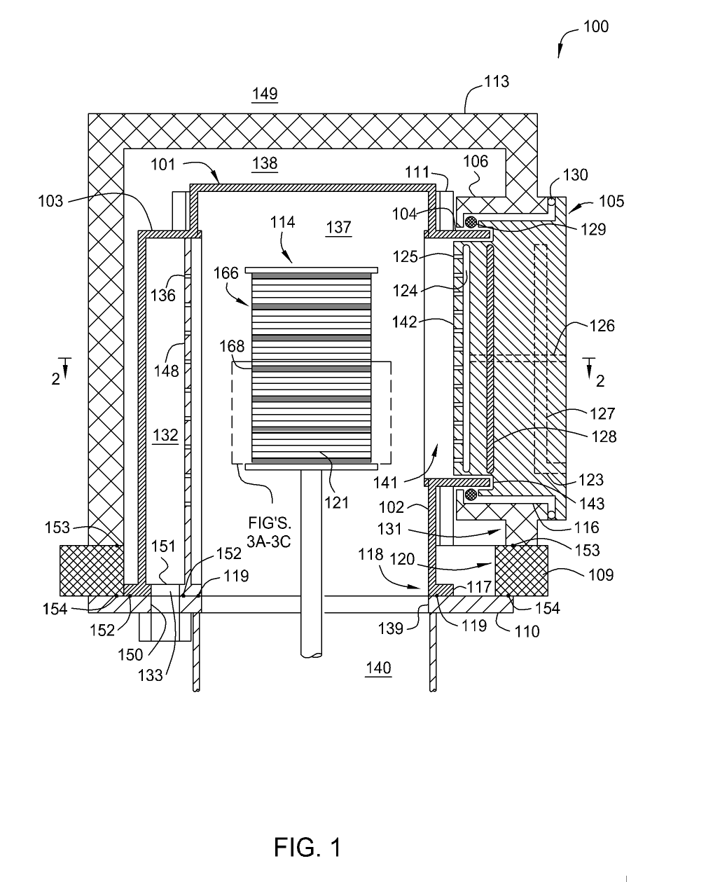

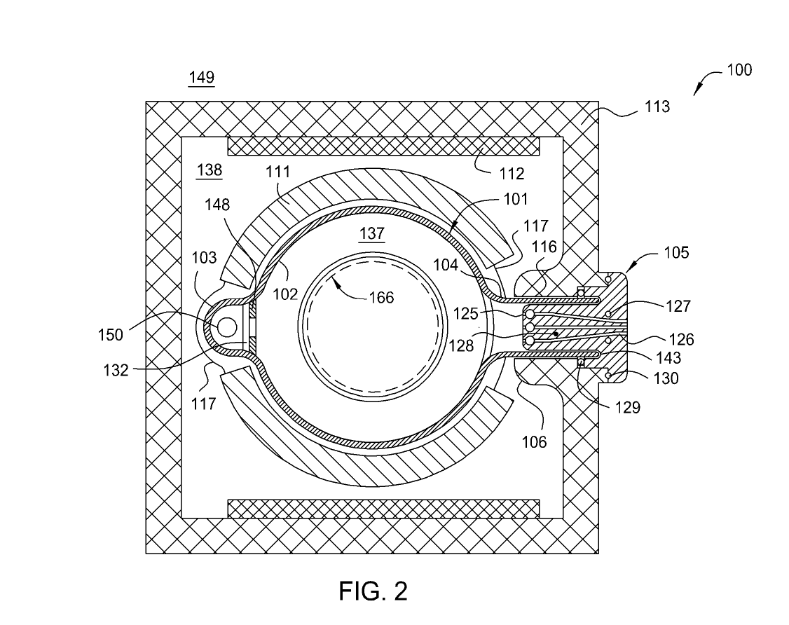

FIG. 1 is a schematic side view of a batch processing chamber 100 and FIG. 2 is a schematic cross-sectional top view of the batch processing chamber 100 along direction 2-2 shown in FIG. 1. The batch processing chamber 100 generally comprises a quartz chamber 101 defining a process volume 137 configured to accommodate a batch of substrates 121 stacked in a substrate boat 114. In one aspect, the substrate boat 114 may also include removable susceptors 168. One or more heater blocks 111 are generally arranged around the quartz chamber 101 and are configured to heat the substrates 121 inside the process volume 137. An outer chamber 113 is disposed over the quartz chamber 101 and the one or more heater blocks 111. The outer chamber 113 may have a lower opening 131. One or more thermal insulators 112 (see FIG. 2) may be disposed between the outer chamber 113 and the one or more heater blocks 111, which are configured to reduce heating of the outer chamber 113. The quartz chamber 101 is supported by a quartz support plate 110. The outer chamber 113 is connected to a chamber stack support 109 which has opening 120 and is supported by the quartz support plate 110. O-rings 153 and 154 may be disposed between the chamber stack support 109 and quartz support plate 110 to seal the outer volume 138 from exterior volume 149 which is outside the processing chamber 100.

The quartz chamber 101 generally comprises a chamber body 102 having a bottom opening 118, an inject pocket 104 formed on one side of the chamber body 102, an exhaust pocket 103 formed on the chamber body 102 on an opposite side of the inject pocket 104, and a flange 117 formed adjacent to the bottom opening 118. The exhaust pocket 103 and the inject pocket 104 may be quartz pieces which are welded or fused to the quartz chamber body 102. In another embodiment, the exhaust pocket 103 and the inject pocket 104 may be milled on the chamber body 102. The exhaust pocket 103 has a bottom port 151 and opens at the bottom. An exhaust block 148 is disposed between the chamber body 102 and the exhaust pocket 103 and is configured to limit fluid communication between the process volume 137 and an exhaust volume 132 of the exhaust pocket 103. The flange 117 may be welded on around the bottom opening 118 and the bottom port 151 and is configured to facilitate vacuum seal for both the chamber body 102 and the exhaust pocket 103. The flange 117 is generally in contact with the quartz support plate 110 which has apertures 150 and 139. The bottom opening 118 aligns with the aperture 139 and the bottom port 151 aligns with aperture 150. An O-ring seal 119 may be disposed between the flange 117 and the quartz support plate 110 to seal the process volume 137 from an outer volume 138 defined by the outer chamber 113, the chamber stack support 109, the quartz support plate 110, and the quartz chamber 101. An O-ring 152 is disposed around the bottom port 151 to seal the exhaust volume 132 and the outer volume 138. The quartz support plate 110 is further connected to a load lock chamber 140 where the substrate boat 114 may be loaded and unloaded. The substrate boat 114 may be vertically translated between the process volume 137 and the load lock chamber 140 via the aperture 139 and the bottom opening 118.

Referring to FIG. 2, the heater blocks 111 wrap around an outer periphery of the quartz chamber 101 except near the inject pocket 104 and the exhaust pocket 103. The substrates 121 are heated radiantly to an appropriate temperature by the heater blocks 111 through the quartz chamber 101. In one aspect, the substrate edges 166 are evenly distanced from the quartz chamber 101 because both the substrates 121 and the chamber body 102 are circular. In another aspect, the heater blocks 111 may have multiple controllable zones so that temperature variations between regions may be adjusted, and the zones may be disposed vertically. The vertical zones may extend along the entire length of the substrate boat 114 and each zone may be independently controlled to optimize the heating of the substrates 121. In one embodiment, the heater blocks 111 may have curved surfaces that partially wrap around the quartz chamber 101.

The heater blocks 111 may be vacuum compatible resistive heaters. In one embodiment, the heater blocks 111 may be ceramic heaters which are constructed of a material, such as aluminum nitride, that is resistant to process chemistries, wherein resistive heating elements are hermetically sealed inside the material. In another embodiment, the outer volume 138 may be operated at or near atmospheric pressure, and the heater block 111 comprises a non-sealed resistive heater. In one embodiment, the heater blocks 111 are removable through openings formed on the outer chamber 113 and chamber stack support 109. Removable heating structures used in batch processing are further described in U.S. patent application Ser. No. 11/233,826, entitled “Removable Heater”, and filed Sep. 9, 2005, which is hereby incorporated by reference in its entirety.

Referring to FIG. 1, the inject pocket 104 welded on a side of the chamber body 102 defines an inject volume 141 in communication with the process volume 137. The inject volume 141 generally covers an entire height of the substrate boat 114 when the substrate boat 114 is in a process position such that the inject assembly 105 disposed in the inject pocket 104 may provide a horizontal flow of processing gases to every substrate 121 in the substrate boat 114. In one aspect, the inject assembly 105 has an intruding center portion 142 configured to fit in the inject volume 141. A recess 143 configured to hold walls of the inject pocket 104 is generally formed around the center portion 142. The walls of the inject pocket 104 are generally wrapped around the inject assembly 105. An inject opening 116 is formed on the outer chamber 113 to provide a pathway for the inject assembly 105. A rim 106 extending inward may be formed around the inject opening 116 and may be configured to shield the inject assembly 105 from being heated by the heater blocks 111. In one aspect, the outer volume 138, which generally is inside of the outer chamber 113 and outside of the quartz chamber 101, is kept in a vacuum state. Since the process volume 137 and the inject volume 141 are usually kept in a vacuum state during processing, keeping the outer volume 138 under vacuum can reduce pressure generated stress on the quartz chamber 101. An O-ring seal 130 is disposed between the inject assembly 105 and the outer chamber 113 to provide a vacuum seal for the inject volume 141. A barrier seal 129 is generally disposed outside the inject pocket 104 preventing process chemicals in the process volume 137 and the inject volume 141 from escaping to the outer volume 138. In another aspect, the outer volume 138 may be kept at atmospheric pressure.

Referring to FIG. 2, three inlet channels 126 are milled horizontally across the inject assembly 105. Each of the three inlet channels 126 is configured to supply the process volume 137 with a process gas independently. In one embodiment, a different process gas may be supplied to each inlet channel 126. Each of the inlet channels 126 is connected to a vertical channel 124 formed near an end of the center portion 142. The vertical channels 124 are further connected to a plurality of evenly distributed horizontal holes 125 and form a vertical shower head on the center portion 142 of the inject assembly 105 (shown in FIG. 1). During processing, a process gas first flows from one of the inlet channels 126 to the corresponding vertical channel 124. The process gas then flows into the process volume 137 horizontally through the plurality of horizontal holes 125. In one embodiment, more or less inlet channels 126 may be formed in the inject assembly 105 depending on requirements of the process performed in the batch processing chamber 100. In another embodiment, since the inject assembly 105 may be installed and removed from outside of the outer chamber 113, the inject assembly 105 may be interchangeable to satisfy different needs.

Referring to FIG. 1, one or more heaters 128 are disposed inside the inject assembly 105 adjacent to the inlet channels 126. The one or more heaters 128 are configured to heat the inject assembly 105 to a set temperature and may be made of resistive heater elements, heat exchangers, etc. Cooling channels 127 are formed in the inject assembly 105 outside the one or more heaters 128. In one aspect, the cooling channels 127 provide further control of the temperature of the inject assembly 105. In another aspect, the cooling channels 127 reduce heating of an outer surface of the inject assembly 105. In one embodiment, the cooling channels 127 may comprise two vertical channels drilled slightly in an angle so that they meet on one end. Horizontal inlet/outlet 123 is connected to each of the cooling channels 127 such that a heat exchanging fluid may continually flow through the cooling channels 127. The heat exchanging fluid may be, for example, a perfluoropolyether (e.g., Galden® fluid) that is heated to a temperature between about 30° C. and about 300° C. The heat exchanging fluid may also be water delivered at a desired temperature between about 15° C. to 95° C. The heat exchanging fluid may also be a temperature controlled gas, such as, argon or nitrogen.

The exhaust volume 132 is in fluid communication with the process volume 137 via the exhaust block 148. In one aspect, the fluid communication may be enabled by a plurality of slots 136 formed on the exhaust block 148. The exhaust volume 132 is in fluid communication with pumping devices through a single exhaust port hole 133 located at the bottom of exhaust pocket 103. Therefore, processing gases in the process volume 137 flow into the exhaust volume 132 through the plurality of slots 136, then exit through the exhaust port hole 133. The slots 136 locate near the exhaust port hole 133 would have a stronger draw than the slots 136 away from the exhaust port hole 133. To generate an even draw from top to bottom, sizes of the plurality of slots 136 may be varied, for example, increasing the size of the slots 136 from bottom to top. Batch processing chambers are further described in U.S. patent application Ser. No. 11/249,555 entitled “Reaction Chamber with Opposing Pockets for Gas Injection and Exhaust”, filed Oct. 13, 2005, which is hereby incorporated by reference in its entirety.

It has been observed that the placement of susceptors 168 within the substrate boat 114 at regular intervals between substrates 121 may improve the temperature uniformity of the substrates when compared to a boat which is loaded only with substrates 121. The susceptors 168 may be suitably adapted to have more uniform and higher emissivity than the substrates 121, and this may result in more uniform radiant heating of the substrates. Additionally, increasing the number of susceptors 168 within the substrate boat 114 may further increase the temperature uniformity of the substrates 121. However, more susceptors may reduce the number of substrates which can be loaded into the substrate boat 114, and so the number of susceptors used in the substrate boat 114 may be limited by throughput considerations.

The use of susceptors 168 which may be removed from or added to a substrate boat 114 in the present invention provides a measure of flexibility in the choice of susceptor numbers, materials, and geometries, each of which may be adjusted to achieve the desired balance of temperature uniformity, gas flow dynamics, and substrate throughput. In addition, removable susceptors 168 may also facilitate cleaning when in situ cleaning is difficult or impractical for the material being deposited during substrate processing. In this case, the susceptors 168 may be removed from the substrate boat 114 for wet cleaning and replaced with clean susceptors 168 to minimize system down time. Also, should a susceptor 168 break and need replacement, the susceptor 168 can be replaced without replacing the entire substrate boat.

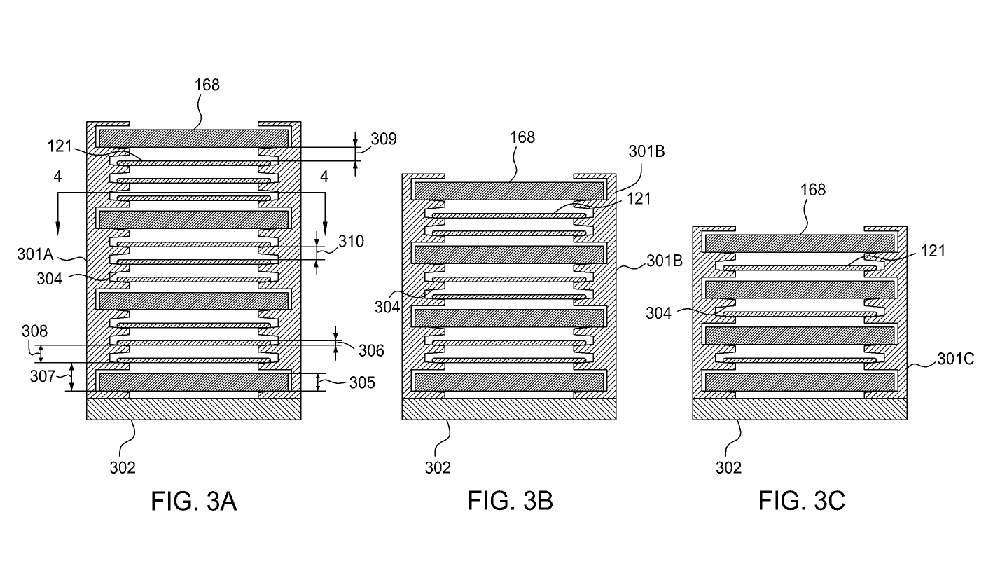

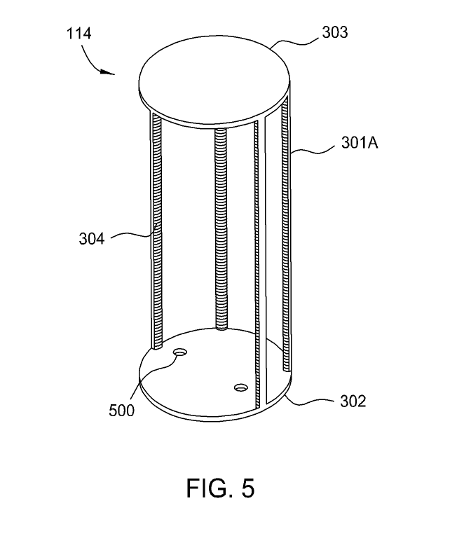

FIGS. 3A-3C are enlarged views of different embodiments of the substrate boat 114 with removable susceptors shown in FIG. 1B. The susceptors 168 may be placed into, or removed, from the substrate boat 114 by a substrate handling robot (not shown). FIG. 3A shows one embodiment which comprises a plurality of vertical supports 301A which are adapted to support three substrates 121 between two susceptors 168. This pattern may be repeated along the length of the substrate boat 114 so that between each adjacent pair of susceptors 168 are disposed three substrates 121. One end of each vertical support 301A may be coupled to a base plate 302, and the other end may be coupled to a top plate 303 (see FIG. 5). In one embodiment, the vertical supports 301A, base plate 302, and top plate 303 may be made of fused quartz and welded together to form the substrate boat 114. In other embodiments, different materials (e.g., silicon carbide) may be used for each of the boat components, as well as different means for coupling the components.

The vertical supports 301A include support fingers 304 which support substrates 121 and susceptors 168. The vertical supports 301A may include a sufficient number of support fingers 304 so that the substrate boat 114 may have a combined carrying capacity of approximately 80 to 115 substrates 121 and susceptors 168. With no susceptors, the substrate boat 114 may have a carrying capacity of about 80 to 115 substrates 121. In other embodiments, the vertical supports may be adapted to include other numbers of support fingers 304 which may increase or decrease the substrate boat 114 capacity outside the ranges mentioned above.

A susceptor 168 may be a circular plate with susceptor thickness 305 which may be greater than substrate thickness 306 to enhance temperature uniformity. In another embodiment, the susceptor thickness 305 may be about equal to the substrate thickness 306. In one embodiment, the susceptor thickness 305 may range from about 0.5 millimeters to about 0.7 millimeters. In another embodiment, the susceptor thickness may be greater than 0.7 millimeters. The susceptor 168 may be larger in diameter than the diameter of the substrate 121 since a larger diameter may improve substrate 121 thermal uniformity by preheating the process gas and reducing thermal edge effects. In other embodiments, the diameters of the susceptors 168 and substrates 121 may be about the same size. In some embodiments, the diameter of the susceptor 168 may be about 200 millimeters or about 300 millimeters. In another embodiment, the diameter of the susceptor 168 may exceed 300 millimeters. The susceptors 168 may be made of solid silicon carbide (SiC). In another embodiment, graphite coated with SiC may be used for the susceptor 168. In yet another embodiment, other materials may be used for the susceptors 168. The choice of material may also be influenced by the desired thermal conductivity of the susceptor 168. In one embodiment of the present invention, a high thermal conductivity material and reduced thickness may be chosen for the susceptor 168 when more rapid heating and cooling cycles are required for substrate processing. In other embodiments, the susceptor 168 may be made of a material with lower thermal conductivity.

Some of the susceptor finger spacings 307 between the support fingers 304 may be larger than the substrate finger spacings 308 so that the substrate boat 114 can receive susceptors 168 which may be thicker than the substrates 121. In other embodiments, the susceptor and substrate finger spacings 307, 308 may be the same. The susceptor-to-substrate spacings 309 and substrate-to-substrate spacings 310 may be chosen to enhance substrate temperature uniformity, gas flow dynamics, and substrate boat 114 holding capacity. In one embodiment, the susceptor-to-substrate spacings 309 and substrate-to-substrate spacings 310 may be equal. In other embodiments, these spacings may differ. The susceptor-to-substrate spacings 309 may range from 5 mm to 15 mm. In other embodiments, the susceptor-to-substrate spacings 309 may lie outside this range.

FIGS. 3B and 3C are enlarged views of other embodiments of the substrate boat 114 with removable susceptors 168 shown in FIG. 1B. FIG. 3B shows vertical supports 301B that are suitably adapted to support two substrates 121 between two susceptors 168. As before, this pattern may be repeated along the substrate boat 114 so that between each adjacent pair of susceptors 168 are disposed two substrates 121. In FIG. 3C, vertical supports 301C are adapted to support one substrate 121 between each adjacent pair of susceptors 168. Other embodiments include any plurality of substrates 121 which may be disposed between adjacent susceptor 168 pairs. In yet another embodiment, the substrate boat 114 may be suitably adapted to include only substrates 121 and no susceptors 168.

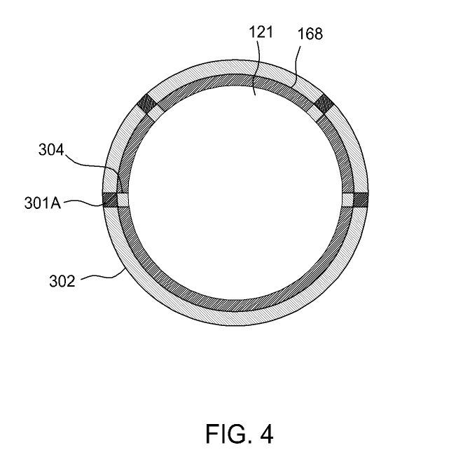

FIG. 4 is a cross-sectional top view of the substrate boat shown in FIG. 3A. A substrate 121 is supported by four support fingers 304 which project from four vertical supports 301A which are coupled (e.g. welded) to a base plate 302. Directly beneath the substrate 121 is a susceptor 168. In this view, the susceptor 168 can be seen because it has a larger diameter than the substrate 121. In one embodiment, the vertical supports 301A may be suitably adapted to receive susceptors 168 that have larger diameters than the substrates 121. In another embodiment, the vertical supports 301A may be adapted to receive susceptors 168 that have diameters approximately equal to the diameters of the substrates 121. The substrate boat 114 may include two or more vertical supports 301A with which to support substrates 121 and susceptors 168, and the vertical supports 301A may be suitably disposed about the base plate 302 to facilitate substrate 121 and susceptor 168 loading and unloading by a substrate-handling robot (not shown).

FIG. 5 is an isometric view of one embodiment for the substrate boat 114 depicted in FIG. 1B. The substrate boat 114 comprises four vertical supports 301A, a base plate 302 and a top plate 303. Each of the vertical supports 301A includes a plurality of support fingers 304 which may support substrates 121 and susceptors 168. The base plate 302, top plate 303, vertical supports 301A, and support fingers 304 may all be made of fused quartz and welded or fused together to form an integral unit. In other embodiments, different materials (e.g., solid silicon carbide) may be used for the substrate boat 114 and elements thereof, as well as different means for connecting the elements. The base plate 302 may also include one or more thru holes 500 to facilitate alignment of the substrate boat 114 to a substrate-handling robot.

While the foregoing is directed to embodiments of the present invention, other and further embodiments of the invention may be devised without departing from the basic scope thereof, and the scope thereof is determined by the claims that follow.

1. A batch processing chamber comprising:
a quartz chamber configured to enclose a process volume;
at least one removable heater disposed outside the quartz chamber, said heater having one or more heating zones;
an outer chamber configured to enclose the quartz chamber and the at least one removable heater;
an inject assembly attached to the quartz chamber for injecting one or more gases into said chamber;
an exhaust pocket disposed on a side of the quartz chamber and opposite the inject assembly; and
a substrate boat disposed within the process volume wherein the substrate boat comprises a plurality of removable susceptors and is adapted to support one or more substrates between an adjacent pair of the removable susceptors.

2. The batch processing chamber of claim 1, wherein the substrate boat further comprises a plurality of support fingers that are adapted to support three substrates that are disposed between the adjacent pair of the removable susceptors.

3. The batch processing chamber of claim 1, further comprising a substrate handling robot positioned for loading and unloading the substrate boat.

4. The batch processing chamber of claim 1, wherein one or more thermal insulators are disposed between the heater block and the outer chamber.

5. The batch processing chamber of claim 1, wherein the quartz chamber comprises:
a chamber body closed at a top end and open at a bottom end;
an inject pocket formed on one side of the cylindrical body; and
an exhaust pocket closed at a top end and open at a bottom end, and connected to the chamber body on an opposite side to the inject pocket.

6. The batch processing chamber of claim 1, wherein the susceptors comprise silicon carbide.

7. The batch processing chamber of claim 1, wherein the susceptors comprise graphite coated with silicon carbide.

8. The batch processing chamber of claim 1, wherein the susceptors have a diameter of about 300 millimeters.

9. The batch processing chamber of claim 1, wherein the susceptors have a thickness of at least 0.7 millimeters.

10. A method for processing a batch of substrates, the method comprising:
disposing a substrate boat having one or more substrates disposed between at least one adjacent pair of susceptors into a process volume defined by a quartz chamber;
heating radiantly the one or more substrates and the at least one adjacent pair of susceptors;
delivering a process gas through an inject assembly having one or more independent vertical channels; and
injecting the process gas into a process volume through a plurality of holes disposed in the inject assembly.

11. The method of claim 10, wherein three substrates are disposed between the at least one adjacent pair of susceptors within the substrate boat.

12. The method of claim 10, wherein the said heating radiantly is obtained by at least one removable heater block disposed outside the quartz chamber and said heater block having at least one vertical heating zone which is independently controllable.

13. The method of claim 10, wherein each of the at least one adjacent pair of susceptors comprise silicon carbide.

14. The method of claim 10, wherein the at least one adjacent pair of susceptors comprise graphite coated with silicon carbide.

15. A substrate boat for a batch processing chamber, comprising:
two or more vertical supports;
a plurality of support fingers; and
a base plate and a top plate coupled to the vertical supports,
wherein two or more of the plurality of support fingers are adapted to support a substrate and two or more of the plurality of support fingers are adapted to support a removable susceptor.

16. The boat of claim 15, wherein the plurality of support fingers are adapted to support substrates that are disposed between adjacent removable susceptors.

17. The boat of claim 15, wherein the boat is adapted for loading and unloading susceptors and substrates into and from the boat using a substrate handling robot.

18. The boat of claim 15, wherein the base plate includes one or more thru holes to facilitate alignment of the boat to a substrate-handling robot.

19. The boat of claim 15, wherein the boat is adapted for receiving susceptors each with a diameter of at least 300 millimeters.

20. The boat of claim 15, wherein the boat is adapted for receiving susceptors each with a thickness of at least 0.7 millimeters.
